(19) United States
(12) Patent Application Publication
(10) Pub. No.: US 2009/0145481 A1
(43) Pub. Date: Jun. 11, 2009

(54) NANO-OPTOELECTRONIC DEVICES

(75) Inventors: Shu-Fen Hu, Hsinchu City (TW); Ting-Wei Liao, Taichung City (TW); Chao-Yuan Huang, Taipei City (TW)

Correspondence Address: QUINTERO LAW OFFICE, PC, 2210 MAIN STREET, SUITE 200, SANTA MONICA, CA, 90405, US

(73) Assignee: SHU-FEN HU, HSINCHU CITY (TW)

(21) Appl. No.: 12/144,542

(22) Filed: Jun. 23, 2008

(30) Foreign Application Priority Data
Dec. 6, 2007 (TW) TW96146493

(51) Int. Cl. H01L 31/00

(52) U.S. Cl. 136/260; 136/252; 136/262

(57) ABSTRACT

Optoelectronic devices with multiple nano-scale quantum dots detecting photons are presented. A nano-optoelectronic device includes a semiconductor substrate, an insulation layer on the semiconductor substrate, and a nano-optoelectronic structure on the insulation layer. The nano-optoelectronic structure includes a positive semiconductor, a negative semiconductor, and a plurality of quantum dots disposed therebetween. A first electrode connects the negative semiconductor, and a second electrode connects the positive semiconductor.

### CROSS REFERENCE TO RELATED APPLICATIONS

This application is based upon and claims the benefit of priority from a prior Taiwanese Patent Application No. 096146493, filed on Dec. 24, 2007, the entire contents of which are incorporated herein by reference.

### BACKGROUND OF THE INVENTION

1. Field of the Invention

The invention relates to nano-optoelectronic devices, and in particular to photodetector devices and photovoltaic (solar cells) with multiple nano quantum dots.

2. Description of the Related Art

As semiconductor technology develops toward the deep sub-micrometer (i.e., nanometer) regime, integration requirements for optoelectronic devices are increased while dimension requirements are decreased. Development of conventional silicon-based optoelectronic devices includes photodetectors (PD), light emitting diodes (LEDs), and photovoltaic (solar cells).

When material dimensions are shrunk to nanometer scale, its physical, optical, and electrical characteristics become extremely different from its bulk material dimensions. For example, a typical low dimensional semiconductor nanostructure includes two dimensional quantum wells, one dimensional quantum wires, and zero dimensional quantum dots, in which quantum dots are usually referred to as nanocrystal with diameter approximately in a range from several to tens of nanometers. The theoretical reason to fabricate nano-optoelectronic device is that energy gap and optical characteristic of the nanocrystal quantum dot structure are changed. Since the volume of the nanocrystal is very small, the quantum dot consists of a three dimensional barrier, i.e., quantum limit effect such that electrons are affected due to the quantum limit effect splitting from a continuous band into discrete energy levels. The density of the electron energy state of the nanocrystal, however, is also different from that of bulk material dimensions. More specifically, the density of the electron energy state of the nanocrystal is between those of atoms and bulk material, but similar to atomic energy levels. Moreover, the density of the electron energy state of the nanocrystal is changed as dimensions of the nanocrystal are changed such that optical, electrical and magnetic characteristics of the nanocrystal can be artificially changed due to the dimensional change.

Photons are basic elements of the photodetector s which can transform an optic signal to an electric signal. When an incident light irradiates a semiconductor photodetector, interaction between Photons and electrons are generated. FIG. 1 is a schematic view of a conventional semiconductor photodetector. Referring to FIG. 1, a conventional semiconductor photodetector includes an n-type semiconductor region 2 with free electrons 1 and a p-type semiconductor region 4 with holes 3. A junction 5 is created between the n-type semiconductor region 2 and the p-type semiconductor region 4. Carrier depletion regions 6 with specific widths are simultaneously formed on both sides of the junction 5. When incident optical signals L, where energy exceeds the direct energy gap or indirect energy gap of the semiconductor materials, irradiate the photodetector device, electron-hole pairs are generated in the carrier depletion regions 6. The electron-hole pairs are further affected by interior electric fields E in the carrier depletion regions 6 separating electron and holes which are injected into the n-type semiconductor region 2 and the p-type semiconductor region 4, causing further conduction to exterior circuit. Photo currents IL are thus generated and can be measured by a current meter 8. Therefore, when the interior electric field E in the carrier depletion regions 6 increases or when the electric potential becomes large, the Photo currents IL increases as the drift speeds of electrons and holes increase. Moreover, the faster the drift speeds, response of the photodetector becomes faster. Conversely, a portion of the separated electrons and holes are recombined with other electrons and holes before being injected from the carrier depletion regions resulting in small Photo currents.

FIG. 2A is a three-dimensional view of a conventional silicon-based photovoltaic (solar cells), while FIG. 2B is a cross section of the silicon-based photovoltaic (solar cells) of FIG. 2A. Referring to FIGS. 2A and 2B, conventional silicon-based photovoltaic (solar cells) 10 includes an n-type semiconductor layer 14 on a p-type semiconductor substrate 12 with a p-n junction 13 therebetween. A finger electrode 16 and an anti-reflection layer (ARC) 17 are disposed on the n-type semiconductor layer 14. An Ohmic contact is disposed on the bottom of the p-type semiconductor substrate 12. When ambient lights L, where energy exceeds the direct energy gap or indirect energy gap of the semiconductor materials, irradiate on the silicon-based photovoltaic (solar cells) 10, an output of Eg is generated by the silicon-based photovoltaic (solar cells) 10, wasting energy (mostly heat energy).

As such, conventional optoelectronic devices do not meet size and efficiency requirements for nano-scale device integration. More specifically, integration of optoelectronic devices with quantum dots to circuits on silicon-based substrate requires embedding nanocrystals in a dielectric medium. The dimensions of the nanocrystals have to be uniform with a diameter of at least, less than 10 nanometers, thereby achieving high densification.

### BRIEF SUMMARY OF THE INVENTION

Accordingly, main and key aspects of the invention are related to nano-optoelectronic devices, which include photodetectors with vertical stacked structures of nano-silicon nitride and polysilicon layers serving as sensing elements, wherein the photodetectors are integrated with a circuit on a silicon-based substrate to create highly integrated and sensitive nano-optoelectronic devices

Embodiments of the invention provide a nano-optoelectronic device, comprising: a substrate; an insulation layer disposed on the substrate; and a nano-optoelectronic structure disposed on the insulation layer, wherein the nano-optoelectronic structure comprises a positive semiconductor, a negative semiconductor, and a plurality of quantum dots interposed therebetween.

Embodiments of the invention further provide a nano-optoelectronic device, comprising: a semiconductor substrate; an insulation layer disposed on the semiconductor substrate; and a photodetector disposed on the insulation layer, comprising a negative semiconductor, a positive semiconductor and a plurality of quantum dots and tunneled junctions therebetween, wherein a first electrode is connected to the negative semiconductor and a second electrode is connected to the positive semiconductor.

Note that the photodetector is a vertical type photodetector with a vertical stacked structure comprising the negative semiconductor, alternately stacked thin insulation and thin semiconductor multi-layers, and the positive semiconductor. Alternatively and optionally, the photodetector is a transverse type photodetector with a horizontal extended structure comprising the negative semiconductor, alternately arranged thin insulation and thin semiconductor multi-layers, and the positive semiconductor.

Embodiments of the invention still further provide a nano-optoelectronic device, comprising: a semiconductor substrate; an insulation layer disposed on the semiconductor substrate; and a photovoltaic (solar cells) disposed on the insulation layer, comprising a plurality of parallel negative semiconductor stripes crossing over a plurality of parallel positive semiconductor stripes, wherein the alternately stacked thin insulation and thin semiconductor multi-layers are disposed at each crossover region and a first electrode is connected to an end of each parallel negative semiconductor stripe and a second electrode is connected to an end of each parallel positive semiconductor stripe.

### BRIEF DESCRIPTION OF THE DRAWINGS

The invention can be more fully understood by reading the subsequent detailed description and examples with references made to the accompanying drawings, wherein:

FIG. 1 is a schematic view of a conventional semiconductor photodetector;

FIG. 2A is a three-dimensional view of a conventional silicon-based photovoltaic (solar cells), while FIG. 2B is a cross section of the silicon-based photovoltaic (solar cells)of FIG. 2A;

FIG. 3A and FIG. 3B are schematic views illustrating energy level states of a nano semiconductor quantum dot before and after irradiation by ambient light, respectively;

FIG. 4 is an equivalent circuit schematically illustrating an embodiment of a nano-optoelectronic device of the invention;

FIG. 5A is a stereographic view of an embodiment of the photodetector device with vertically stacked quantum dot columns of the invention, FIG. 5B is a plan view of the vertically stacked photodetector device of FIG. 5A, while FIG. 5C is a cross section of the vertically stacked photodetector device of FIG. 5A taken along X-axis direction;

FIG. 6A is a stereographic view of another embodiment of the photodetector device with horizontally stacked quantum dot columns, FIG. 6B is a plan view of the horizontally stacked photodetector device of FIG. 6A, while FIG. 6C is a cross section of the horizontally stacked photodetector device of FIG. 6A taken along X-axis direction;

FIG. 7A is a stereographic view of yet another embodiment of the photovoltaic (solar cells) device of the invention, FIG. 7B is a plan view of the photovoltaic (solar cells) device of FIG. 7A, while FIG. 7C is a cross section of the photovoltaic (solar cells) device of FIG. 7A taken along X-axis direction;

FIG. 8 shows I-V characteristics of the vertically stacked photodetector device of FIG. 5A measuring current under a dark state (black line) and 580 nm illumination with optical intensity of 101.7 μW;

FIG. 9 shows I-V characteristics of the vertically stacked photodetector device of FIG. 5A measuring current under continuous 580 nm illumination with increased powers of 101 μW, 125 μW, 178 μW, 290 μW, 396 μW, 498 μW, and 618 μW, respectively;

FIG. 10 shows I-V characteristics of the vertically stacked photodetector device of FIG. 5A measuring current under a dark state, and 580 nm illumination with optical intensity of 396 μW, and a manually chopped 580 nm illumination switched on and off at 5 second intervals during a bias sweep, respectively.

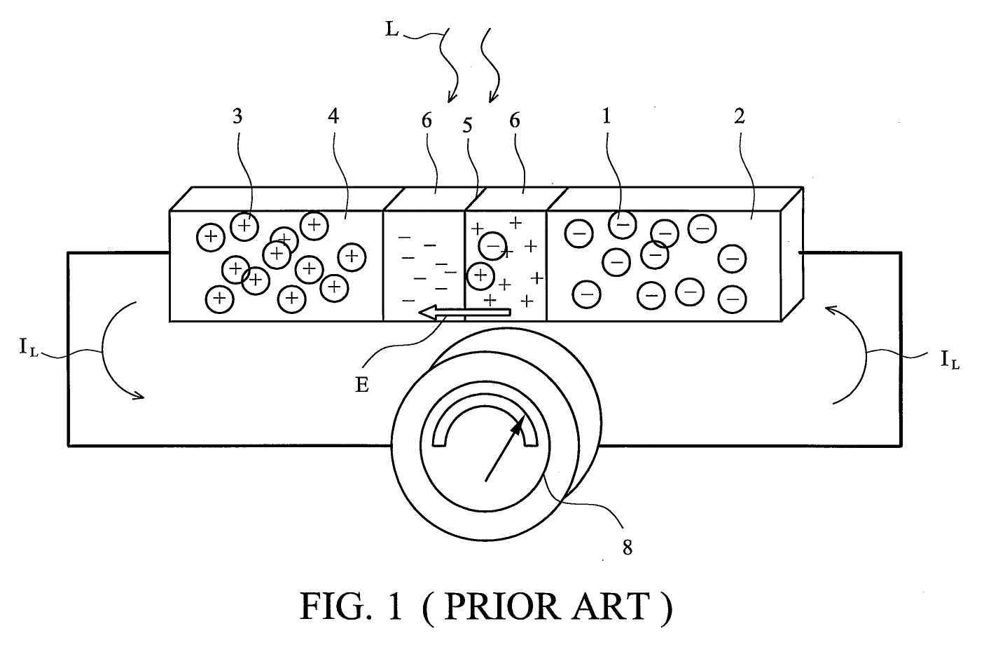

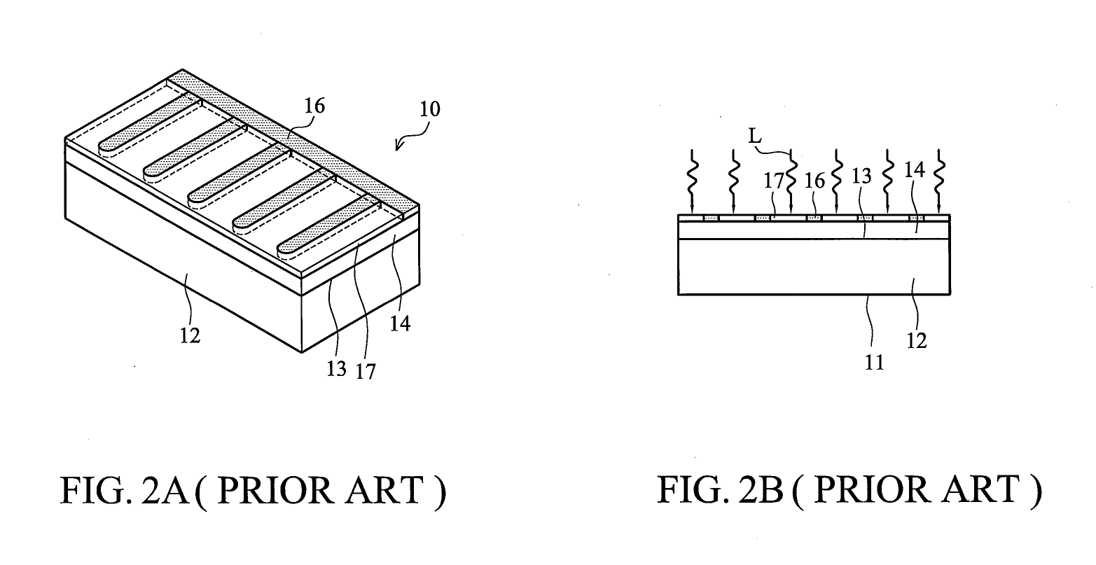

### DETAILED DESCRIPTION OF THE INVENTION

A detailed description is given in the following embodiments with reference to the accompanying drawings.

It is to be understood that the following disclosure provides many different embodiments, or examples, for implementing different features of various embodiments of the invention. Specific examples of components and arrangements are described below to simplify the present disclosure. These are merely examples and are not intended to be limiting. In addition, the present disclosure may repeat reference numerals and/or letters in the various examples. This repetition is for the purpose of simplicity and clarity and does not in itself indicate a relationship between the various embodiments and/or configurations discussed. Moreover, the formation of a first feature over or on a second feature in the description that follows may include embodiments in which the first and second features are formed in direct contact or not in direct contact.

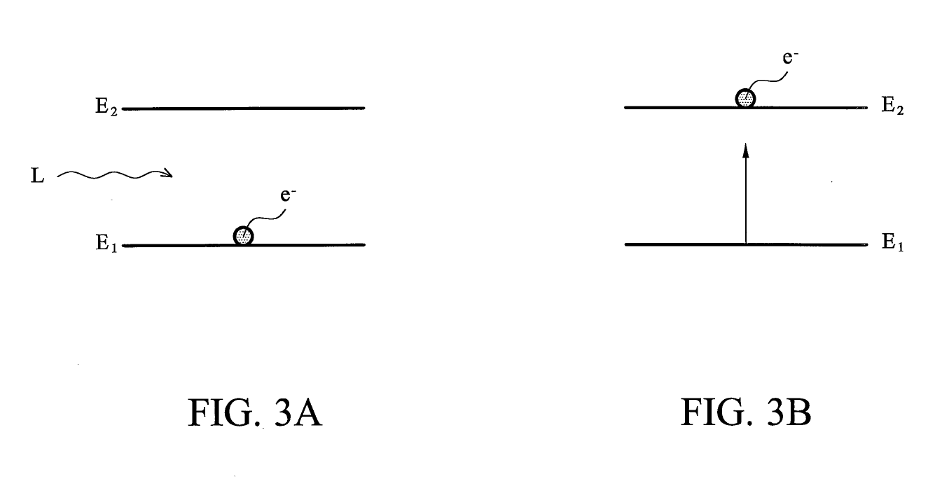

FIG. 3A and FIG. 3B are schematic views illustrating energy level states of a nano semiconductor quantum dot before and after irradiation by ambient light, respectively. Referring to FIG. 3A, the energy level states of a nano semiconductor quantum dot is similar to the energy level states of an atom. Two adjacent energy levels E₁ and E₂ are considered in which E₁ corresponds to a ground state while E₂ corresponds to an excited state. The electron on the energy level E₁ absorbs incident light energy and excites to the excited energy level E₂. This process is usually referred to as absorption, as shown in FIG. 3B.

If the energy of the incident light equal or exceeds the energy gap between the two adjacent energy levels E₁ and E₂ (i.e., hv=E₂−E₁), electrons in the nano semiconductor quantum dot can absorb energy of the photons, thereby generating electron-hole pairs therein. The electron-hole pairs in the nano-optoelectronic devices is driven and divided such that electrons and holes resonant tunneled between the quantum dots. Optoelectric currents are thus output.

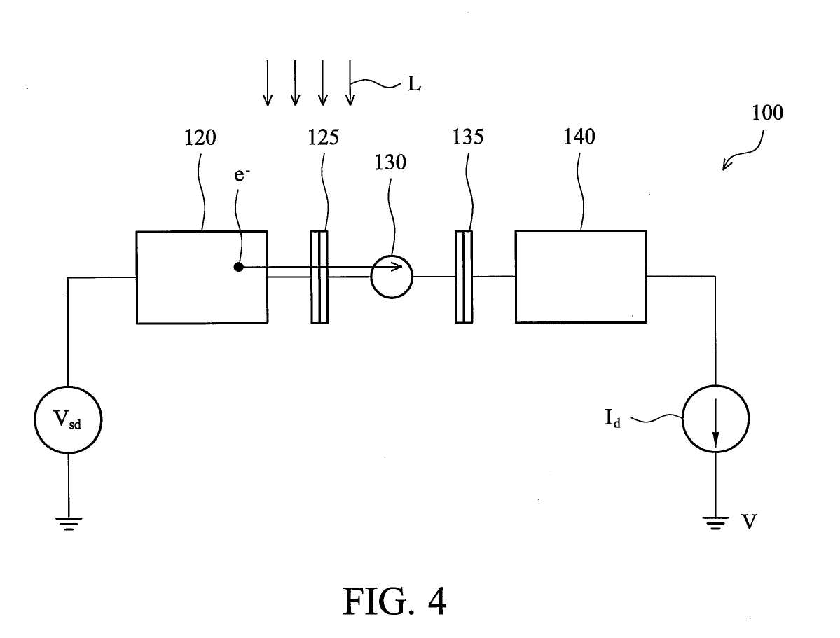

FIG. 4 is an equivalent circuit schematically illustrating an embodiment of a nano-optoelectronic device of the invention. The primary circuit of the nano-optoelectronic device 100 includes a negative semiconductor 120, a positive semiconductor 140, and at least one nano semiconductor quantum dot 130 interposed between the negative semiconductor 120 and the positive semiconductor 140. The dimensions of the nano semiconductor quantum dot 130 are nano scale such as less than 20 nm to exhibit quantum effect. Ultra thin tunnel junctions 125 and 135 such as silicon nitride layers are separately and the quantum dot 130 interposed between the negative semiconductor 120 and the positive semiconductor 140. When an ambient light signal L illuminates on the nano-optoelectronic device 100, if the energy of the incident light signal L exceeds the energy gap of the nano semiconductor quantum dot 130, the generated electron-hole pairs are affected by interior field or voltage V_{ds}, and then are separated generating photo current I_{d} which is analyzed by Amp meter.

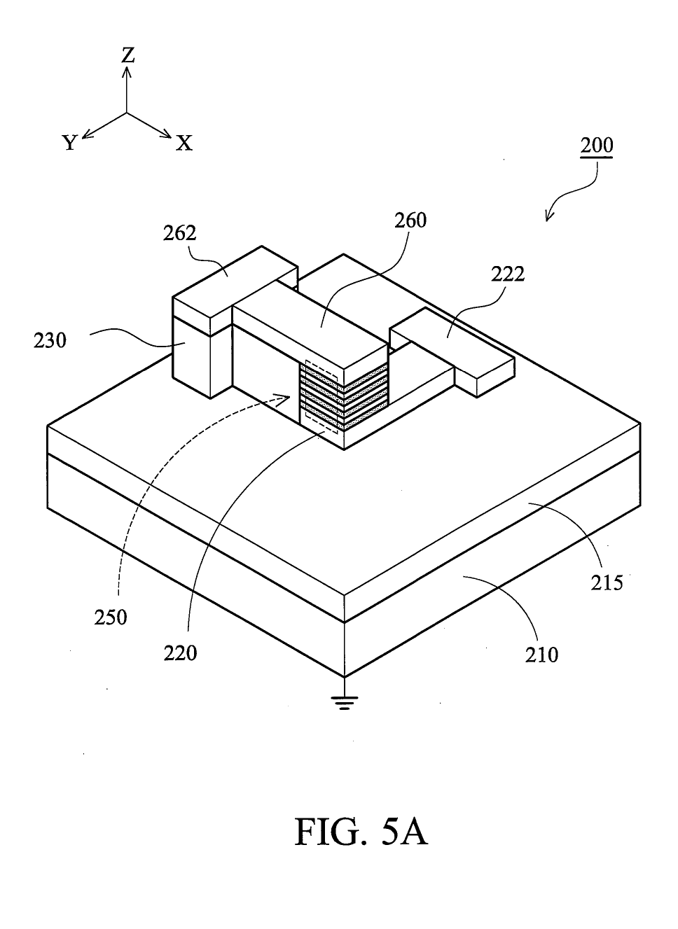

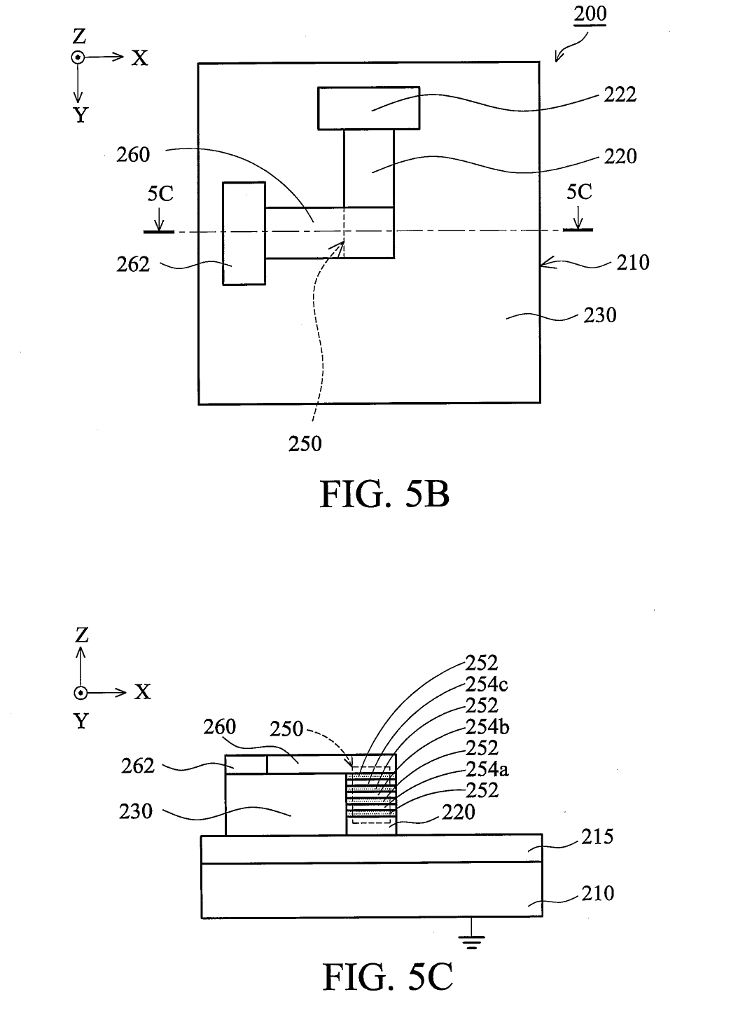

FIG. 5A is a stereographic view of an embodiment of the photodetector device with vertically stacked quantum dot columns of the invention, FIG. 5B is a plan view of the vertically stacked photodetector device of FIG. 5A, while FIG. 5C is a cross section of the vertically stacked photodetector device of FIG. 5A taken along X-axis direction. Referring to FIG. 5A, a vertically stacked pillar type photodetector device 200 includes a semiconductor substrate 210 such as a silicon substrate. An insulation layer 215 is formed on the semiconductor substrate 210. The insulation layer 215 is made of a silicon dioxide (e.g., a wet silicon oxide layer) or a tetra-ortho-silicate (TEOS) with a thickness in a range of approximately between 2000 Å and 4000 Å. A nano photodetector element is disposed on the insulation layer 215, including a negative semiconductor 220, a positive semiconductor 260, and multiple quantum dots and tunneled junctions stacked structure 250 interposed between the negative semiconductor 220 and the positive semiconductor 260. A first electrode 222 connects the negative semiconductor 220, and a second electrode 262 connects the positive semiconductor 260.

The multiple quantum dots and tunneled junctions stacked structure 250 includes, vertically stacked multiple insulation layers 252 and thin semiconductor layers 254a-254c stacked structure, which are defined by electron beam lithography, etching, and oxidizing. Nano scale silicon islands are thus formed, as shown in FIG. 5C. The thin insulation layer 252 is made of gallium phosphide (GaP), silicon nitride (SiNₓ), silicon oxide (SiOₓ), or silicon oxynitride (SiON) with thickness in a range of approximately between 1 nm and 10 nm. The thin semiconductor layers 254a-254c are made of gallium arsenide (GaAs), gallium indium phosphide (GaInP), indium gallium arsenide nitride (GaInNAs), indium gallium arsenide phosphide (GaInPAs), aluminum gallium arsenide (AlGaAs), aluminum indium arsenide (AlInAs), aluminum gallium indium phosphide (AlGaInP), aluminum gallium indium arsenic phosphide (AlGaInAsP), indium phosphide (InP), indium arsenide (InAs), indium aluminum arsenide (InAlAs), indium gallium arsenide (InGaAs), cadmium selenide (CdSe), zinc selenide (ZnSe), zinc sulphide (ZnS), cadmium sulphide (CdS), zinc telluride (ZnTe), cadmium telluride (CdTe), silicon (Si), germanium (Ge), or silicon germanium (SiGe). The thickness of the thin semiconductor layers 254a-254c is in a range of approximately between 1 nm and 10 nm.

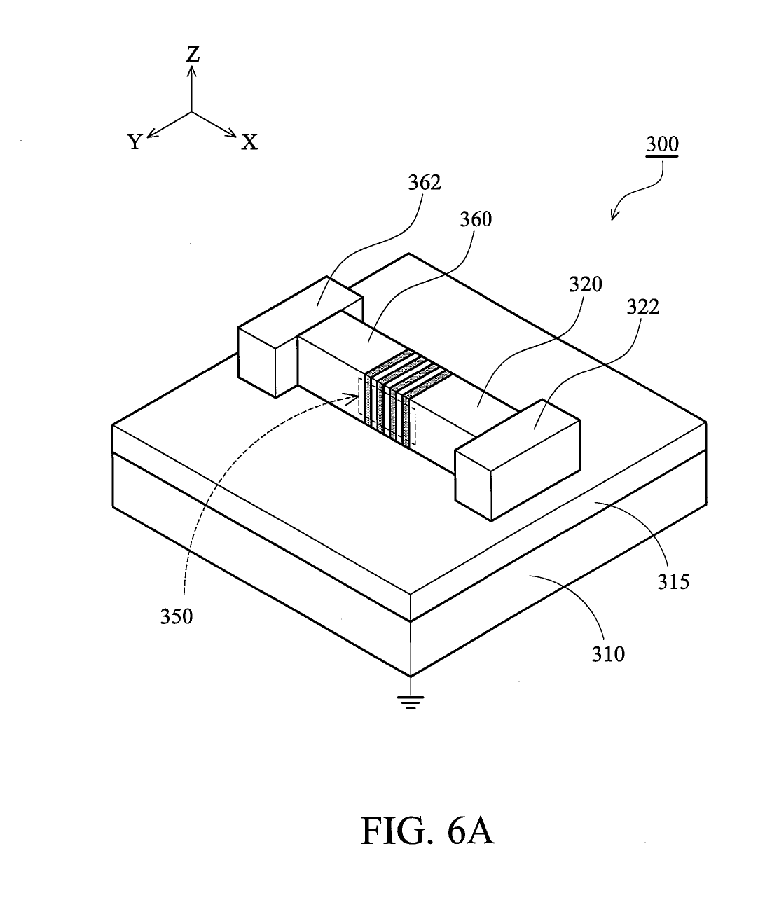

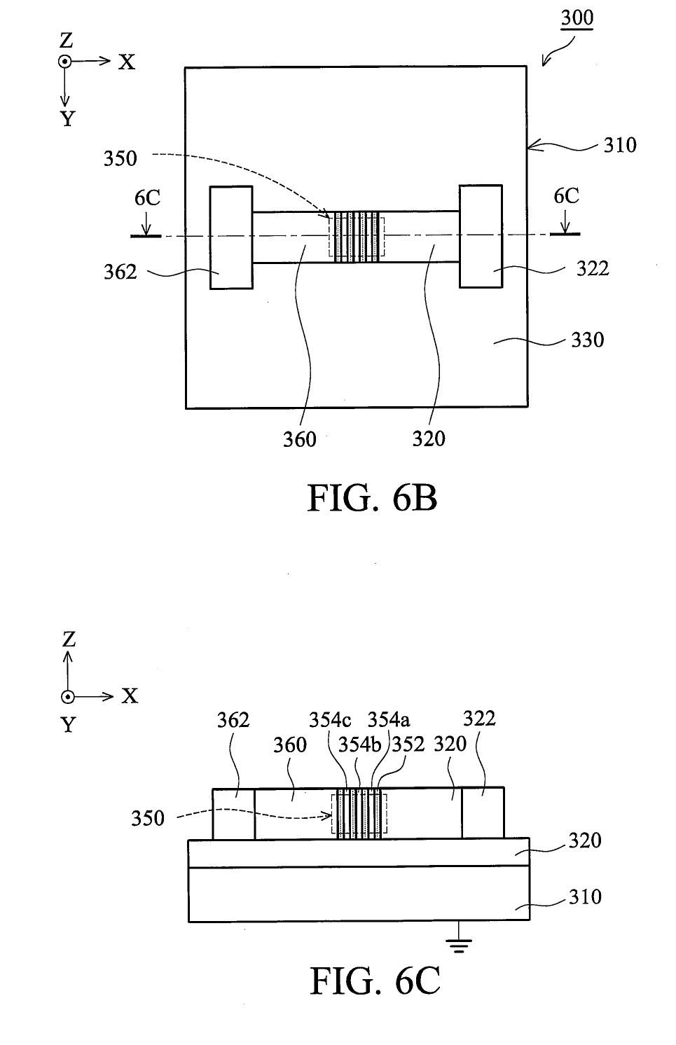

FIG. 6A is a stereographic view of another embodiment of the photodetector device with horizontally stacked quantum dot pillar, FIG. 6B is a plan view of the horizontally stacked photodetector device of FIG. 6A, while FIG. 6C is a cross section of the horizontally stacked photodetector device of FIG. 6A taken along X-axis direction.

Referring to FIG. 6A, a horizontally stacked photodetector device 300 includes a semiconductor substrate 310 such as a silicon substrate. An insulation layer 315 is formed on the semiconductor substrate 310. The insulation layer 315 is made of a silicon dioxide (e.g., a wet silicon oxide layer) or a tetra-ortho-silicate (TEOS) with a thickness in a range of approximately between 2000 Å and 4000 Å. A horizontally stacked nano photodetector element is disposed on the insulation layer 315, including a negative semiconductor 320, a positive semiconductor 360, and a multiple quantum dots and tunneled junctions extended structure 350 interposed between the negative semiconductor 320 and the positive semiconductor 360. A first electrode 322 connects the negative semiconductor 320, and a second electrode 362 connects the positive semiconductor 360.

The multiple quantum dots and tunneled junctions extended structure 350 includes, horizontally arranged multiple insulation layers 352 and thin semiconductor layers 354a-354c structure, which are defined by electron beam lithography, etching, and oxidizing. Nano scale silicon islands are thus formed, as shown in FIG. 6C. The thin insulation layer 352 is made of gallium phosphide (GaP), silicon nitride (SiNₓ), silicon oxide (SiOₓ), or silicon oxynitride (SiON) with thickness in a range of approximately between 1 nm and 10 nm. The thin semiconductor layers 354a-354c are made of GaAs, GaInP, GaInNAs, GaInPAs, AlGaAs, AlInAs, AlGaInP, AlGaInAsP, InP, InAs, InAlAs, InGaAs, CdSe, ZnSe, ZnS, CdS, ZnTe, CdTe, Si, Ge, or SiGe with a thickness in a range of approximately between 1 nm and 10 nm.

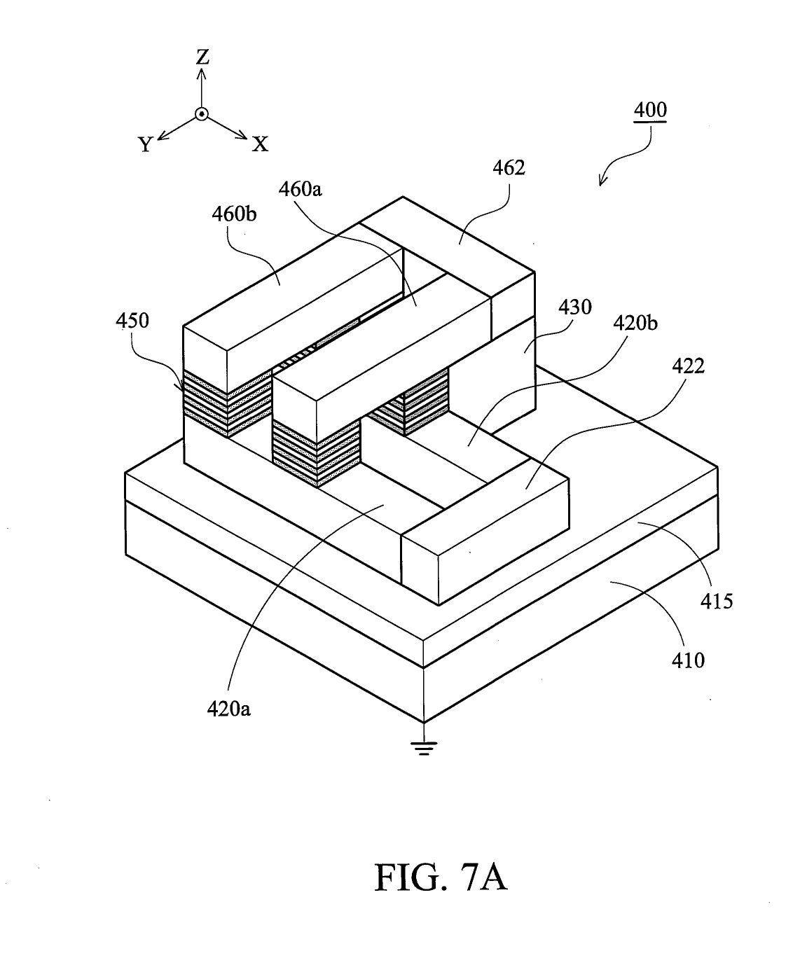

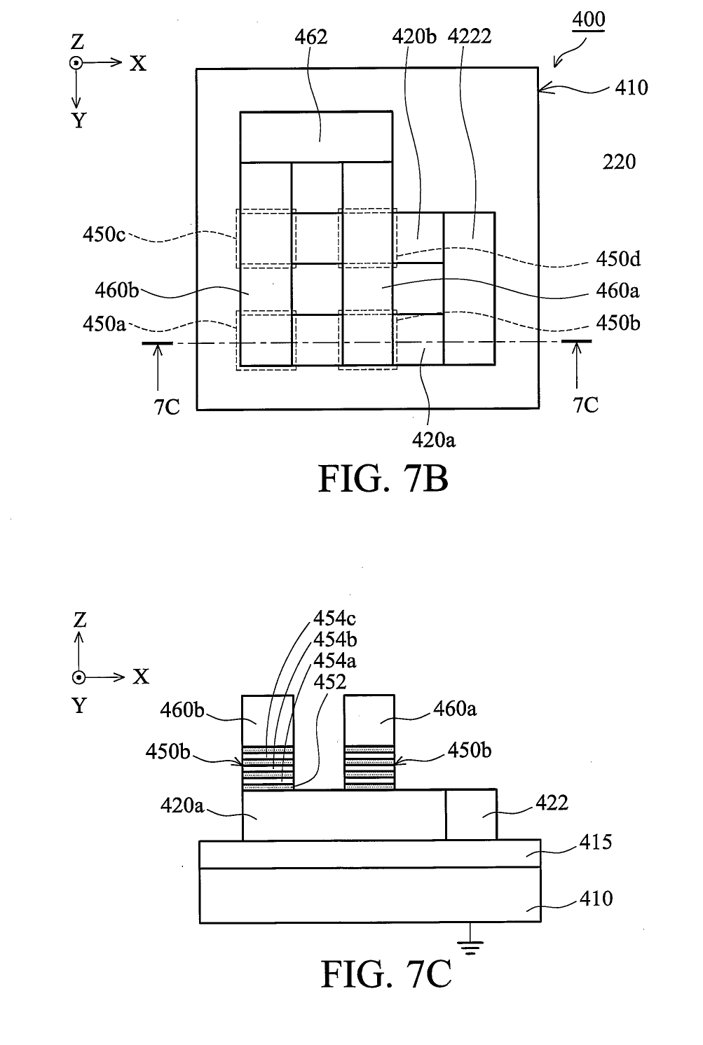

FIG. 7A is a stereographic view of further another embodiment of the photovoltaic (solar cells) device of the invention, FIG. 7B is a plan view of the photovoltaic (solar cells) device of FIG. 7A, while FIG. 7C is a cross section of the photovoltaic (solar cells) device of FIG. 7A taken along X-axis direction.

Referring to FIG. 7A, a photovoltaic (solar cells) device 400 includes a semiconductor substrate 410 such as a silicon substrate. An insulation layer 415 is formed on the semiconductor substrate 410. The insulation layer 415 is made of a silicon dioxide (e.g., a wet silicon oxide layer) or a tetra-ortho-silicate (TEOS) with a thickness in a range of approximately between 2000 Å and 4000 Å. A photovoltaic (solar cells) element is disposed on the insulation layer 415, including a plurality of parallel negative semiconductor stripes 420a-420b crossing over a plurality of parallel positive semiconductor stripes 460a-460b, wherein vertically alternated stacked multi-layers of, thin insulation layers 452 and thin semiconductor layers 454a-454c, are disposed at each crossover region. A first electrode 422 connects the negative semiconductor stripes 420a-420b, and a second electrode 362 connects the positive semiconductor stripes 460a-460b.

The thin insulation layer 452 is made of gallium phosphide (GaP), silicon nitride (SiNₓ), silicon oxide (SiO_{y}), or silicon oxynitride (SiON) with thickness in a range of approximately between 1 nm and 10 nm. The thin semiconductor layers 454a-454c are made of GaAs, GaInP, GaInNAs, GaInPAs, AlGaAs, AlInAs, AlGaInP, AlGaInAsP, InP, InAs, InAlAs, InGaAs, CdSe, ZnSe, ZnS, CdS, ZnTe, CdTe, Si, Ge, or SiGe with a thickness in a range of approximately between 1 mm and 10 m.

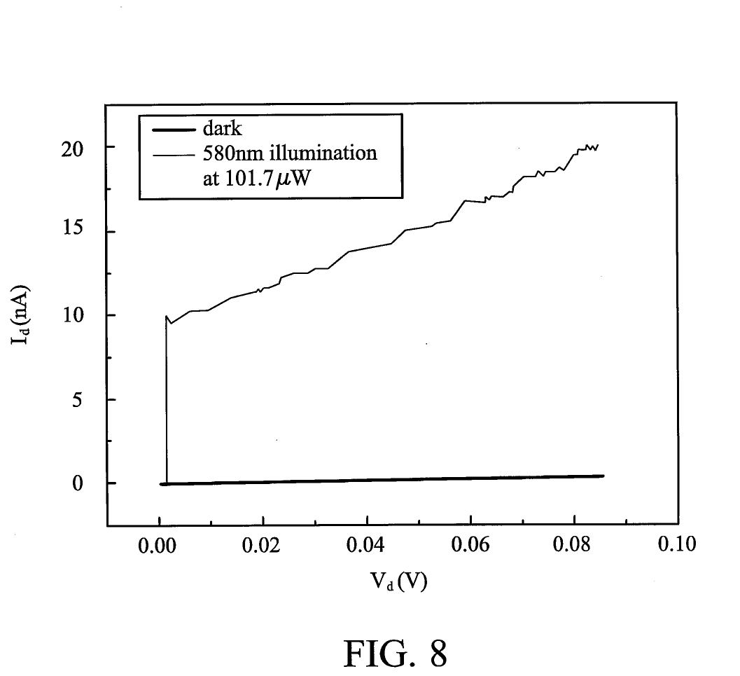

FIG. 8 shows I-V characteristics of the vertically stacked photodetector device of FIG. 5A measuring current under a dark state (black line) and 580 nm illumination with optical intensity of 101.7 μW. Referring to FIG. 8, the photoconductivity measurements of the vertically stacked photodetector device 200 of FIG. 5A can be performed using an optical microscope with an intensity controllable illumination apparatus providing various intensities of about 580 nm illumination. At operation temperature T=300K, V_{d}−I_{d} characteristic curves of the vertically stacked photodetector device in which low bias from about +0V to +0.1 volts are applied between the positive and the negative semiconductors are respectively measured under a dark state (black line) and measured by various intensities (power) of ˜580 nm illumination. Apparently, it can be seen that the vertically stacked photodetector device exhibits a low current regime over a considerable voltage range in the dark state (black line) which implies that the vertically stacked photodetector device has very high resistance of about 10⁸Ω. On the contrary, upon illumination bias, a marked increase in the measured current is observed across the entire bias range. Nevertheless, current staircases (i.e., Coulomb staircases) can be seen clearly when increasing intensity above 101.7 μW.

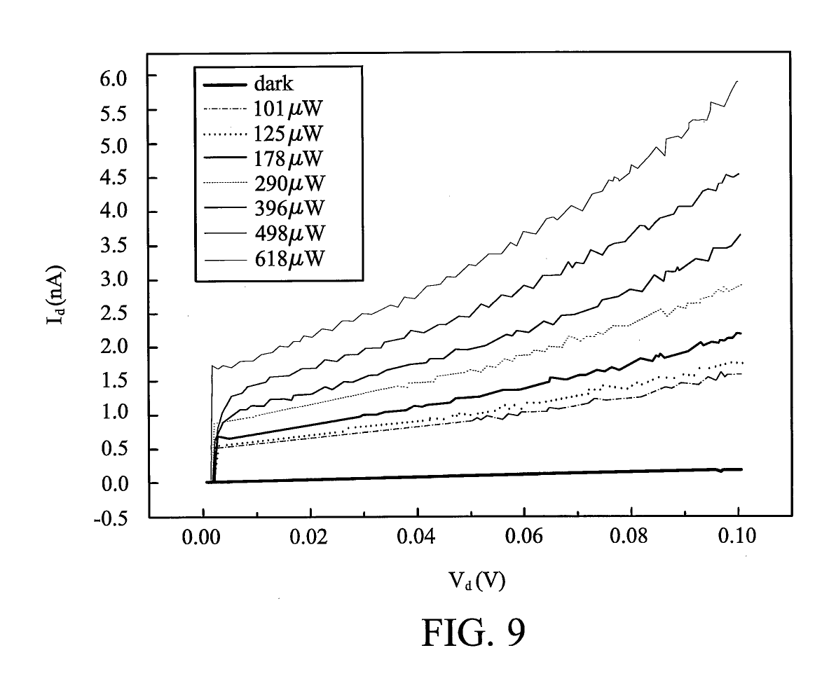

To gain more insight into this quantum phenomenon, I-V characteristics of the vertically stacked photodetector device of FIG. 5A are further measured under continuous 580 nm illumination with increased powers of 101 μW, 125 μW, 178 μW, 290 μW, 396 μW, 498 μW, and 618 μW, as shown in FIG. 9. The photocurrent Id increases as the illumination intensity is increased. This phenomenon may be due to the Coulomb interaction resulting from the capture of a single photoexcited carrier by quantum dots. Additionally, the current oscillations increase when illumination intensity increases.

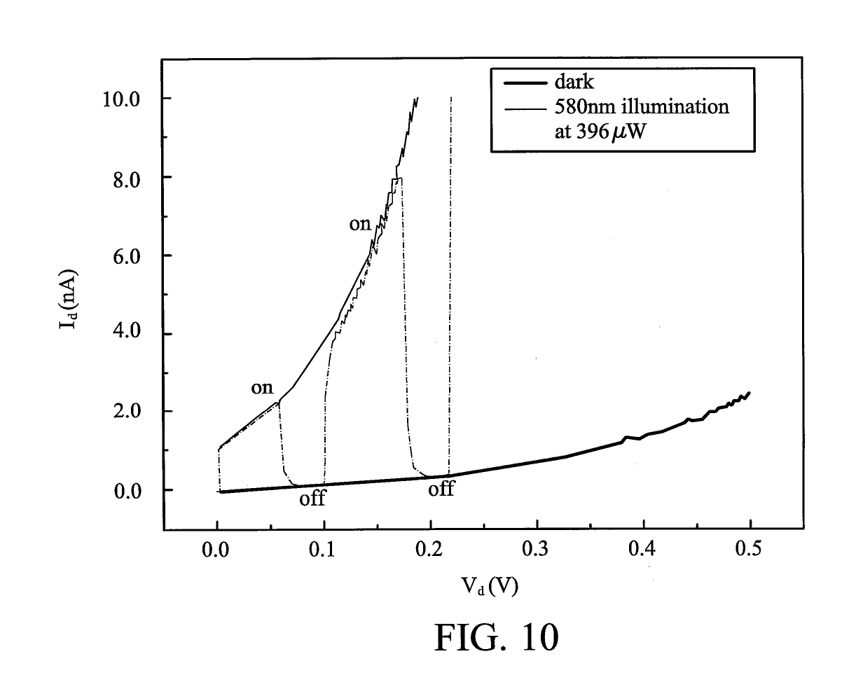

FIG. 10 shows I-V characteristics of the vertically stacked photodetector device of FIG. 5A, measuring current under a dark state, 580 nm illumination with optical intensity of 396 μW, and manually chopped 580 nm illumination switched on and off at 5 second intervals during the bias sweep, respectively. The coarse dark curve of the vertically stacked photodetector device measured at a dark state exhibits quasilinear characteristics. On the contrary, a dramatic increase in the measured current Id is observed across the entire bias range under 580 nm illumination with optical intensity of 396 μW. Furthermore, the observed I-V curve (dashed line) measured under manually chopped 580 nm illumination switched on and off at 5 second intervals during the bias sweep clearly exhibits almost full recovery of the device after illumination is removed.

The above mentioned embodiments of the invention provide nano-optoelectronic devices including a vertical type photodetector, a transverse type photodetector, and a photovoltaic (solar cells). Since the alternately stacked thin insulation and thin semiconductor multi-layers can serve as a detection element and can be integrated with a silicon-based substrate and processes, nano-optoelectronic devices with high integration and high sensitivity can be thus achieved.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A nano-optoelectronic device, comprising:
a substrate;
an insulation layer disposed on the substrate; and
a nano-optoelectronic structure disposed on the insulation layer,
wherein the nano-optoelectronic structure comprises a positive semiconductor, a negative semiconductor, and a plurality of quantum dots and tunneled junctions interposed therebetween.

2. The nano-optoelectronic device as claimed in claim 1, wherein the substrate is a semiconductor substrate.

3. The nano-optoelectronic device as claimed in claim 1, wherein the insulation layer is made of a silicon dioxide or a tetra-ortho-silicate (TEOS), with thickness in a range of approximately between 2000 Å and 4000 Å.

4. The nano-optoelectronic device as claimed in claim 1, further comprising a first electrode connected to the negative semiconductor, and a second electrode connected to the positive semiconductor.

5. The nano-optoelectronic device as claimed in claim 4, wherein the nano-optoelectronic device is a photodetector or a photovoltaic (solar cells).

6. The nano-optoelectronic device as claimed in claim 5, wherein the photodetector is a vertical type photodetector with a vertical stacked structure comprising the negative semiconductor, alternately stacked thin insulation and thin semiconductor multi-layers, and the positive semiconductor.

7. The nano-optoelectronic device as claimed in claim 5, wherein the photodetector is a transverse type photodetector with a horizontal extended structure comprising the negative semiconductor, alternately arranged thin insulation and thin semiconductor multi-layers, and the positive semiconductor.

8. The nano-optoelectronic device as claimed in claim 5, wherein the photovoltaic (solar cells) comprises a plurality of parallel negative semiconductor stripes crossing over a plurality of parallel positive semiconductor stripes, wherein alternately stacked thin insulation and thin semiconductor multi-layers are disposed at each crossover region.

9. The nano-optoelectronic device as claimed in claim 8, wherein the first electrode connects an end of each parallel negative semiconductor stripe, and the second electrode connects an end of each parallel positive semiconductor stripe.

10. A nano-optoelectronic device, comprising:
a semiconductor substrate;
an insulation layer disposed on the semiconductor substrate; and
a photodetector disposed on the insulation layer, comprising a negative semiconductor, a positive semiconductor and a plurality of quantum dots and tunneled junctions therebetween; and
a first electrode connected to the negative semiconductor and a second electrode connected to the positive semiconductor.

11. The nano-optoelectronic device as claimed in claim 10, wherein the insulation layer is made of a silicon dioxide or a tetraorthosilicate (TEOS), with thickness in a range of approximately between 2000 Å and 4000 Å.

12. The nano-optoelectronic device as claimed in claim 10, wherein the photodetector is a vertical type photodetector with a vertical stacked structure comprising the negative semiconductor, alternately stacked thin insulation and thin semiconductor multi-layers, and the positive semiconductor.

13. The nano-optoelectronic device as claimed in claim 10, wherein the photodetector is a transverse type photodetector with a horizontal extended structure comprising the negative semiconductor, alternately arranged thin insulation and thin semiconductor multi-layers, and the positive semiconductor.

14. The nano-optoelectronic device as claimed in claim 12, wherein the thin insulation layer is made of gallium phosphide (GaP), silicon nitride (SiNₓ), silicon oxide (SiO_{y}), or silicon oxynitride (SiON).

15. The nano-optoelectronic device as claimed in claim 12, wherein the thickness of the thin insulation layer is approximately in a range of between 1 mm and 10 nm.

16. The nano-optoelectronic device as claimed in claim 12, wherein the thin semiconductor layer is made of gallium arsenide (GaAs), gallium indium phosphide (GaInP), indium gallium arsenide nitride (GaInNAs), indium gallium arsenide phosphide (GaInPAs), aluminum gallium arsenide (AlGaAs), aluminum indium arsenide (AlInAs), aluminum gallium indium phosphide (AlGaInP), aluminum gallium indium arsenic phosphide (AlGaInAsP), indium phosphide (InP), indium arsenide (InAs), indium aluminum arsenide (InAlAs), indium gallium arsenide (InGaAs), cadmium selenide (CdSe), zinc selenide (ZnSe), zinc sulphide (ZnS), cadmium sulphide (CdS), zinc telluride (ZnTe), cadmium telluride (CdTe), silicon (Si), germanium (Ge), or silicon germanium (SiGe).

17. The nano-optoelectronic device as claimed in claim 12, wherein the thickness of the thin semiconductor layer is in a range of approximately between 1 nm and 10 nm.

18. A nano-optoelectronic device, comprising:
a semiconductor substrate;
an insulation layer disposed on the semiconductor substrate; and
a photovoltaic (solar cells) disposed on the insulation layer, comprising a plurality of parallel negative semiconductor stripes crossing over a plurality of parallel positive semiconductor stripes, wherein alternately stacked thin insulation and thin semiconductor multi-layers are disposed at each crossover region; and
a first electrode connected to an end of each parallel negative semiconductor stripe, and a second electrode connected to an end of each parallel positive semiconductor stripe.

19. The nano-optoelectronic device as claimed in claim 18, wherein the insulation layer is made of a silicon dioxide or a tetraorthosilicate (TEOS), with thickness in a range of approximately between 2000 Å and 4000 Å.

20. The nano-optoelectronic device as claimed in claim 18, wherein the thin insulation layer is made of gallium phosphide (GaP), silicon nitride (SiNₓ), silicon oxide (SiOₓ), or silicon oxynitride (SiON).

21. The nano-optoelectronic device as claimed in claim 18, wherein the thickness of the thin insulation layer is in a range of approximately between 1 nm and 10 nm.

22. The nano-optoelectronic device as claimed in claim 18, wherein the thin semiconductor layer is made of gallium arsenide (GaAs), gallium indium phosphide (GaInP), indium gallium arsenide nitride (GaInNAs), indium gallium arsenide phosphide (GaInPAs), aluminum gallium arsenide (AlGaAs), aluminum indium arsenide (AlInAs), aluminum gallium indium phosphide (AlGaInP), aluminum gallium indium arsenic phosphide (AlGaInAsP), indium phosphide (InP), indium arsenide (InAs), indium aluminum arsenide (InAlAs), indium gallium arsenide (InGaAs), cadmium selenide (CdSe), zinc selenide (ZnSe), zinc sulphide (ZnS), cadmium sulphide (CdS), zinc telluride (ZnTe), cadmium telluride (CdTe), silicon (Si), germanium (Ge), or silicon germanium (SiGe).

23. The nano-optoelectronic device as claimed in claim 18, wherein the thickness of the thin semiconductor layer is in a range of approximately between 1 nm and 10 nm.
